(19) United States
(12) Patent Application Publication
(10) Pub. No.: US 2006/0144336 A1
(43) Pub. Date: Jul. 6, 2006

(54) Heater of chemical vapor deposition apparatus for manfuacturing a thin film

(76) Inventor: Pyung Yong Um, Kyungki-do (KR)

Correspondence Address: Dinsmore & Shohl, LLP, 1900 Chemed Center, 255 East Fifth Street, Cincinnati, OH, 45202, US

(21) Appl. No.: 10/544,602

(22) PCT Filed: Feb. 6, 2003
(86) PCT No.: PCT/KR03/00264

§ 371 Date: Aug. 4, 2005

(51) Int. Cl. C23F 1/00; C23C 16/00

(52) U.S. Cl. 118/725; 156/345.52

(57) ABSTRACT

The present invention relates to a heater of a chemical vapor deposition apparatus for depositing a thin film on the upper part of a wafer. Under the present invention, a thermal insulation reflecting plate made of ceramic or metal is formed on the lower part of the heater, on which the wafer is placed in safety. Temperature all over the heater is maintained uniformly by virtue of the thermal insulation reflecting plate, whereby a material film of uniform thickness is deposited on the upper part of the wafer.

### TECHNICAL FIELD

The present invention relates to a chemical vapor deposition apparatus for depositing a thin film on the surface of a wafer, and more particularly to a chemical vapor deposition apparatus with a thermal insulation reflecting plate made of ceramic or metal provided below a heater, on which a wafer is placed, the thermal insulation reflecting plate maintaining uniformly temperature of the heater, whereby a material film of uniform thickness is deposited on the surface of the wafer.

### BACKGROUND ART

As well known to those skilled in the art, a RC delay by wiring is becoming one of critical factors determining the operating speed of a semiconductor device because of a rapid decrease of a design rule as the size and weight of a device using a semiconductor are reduced. Accordingly, a wiring structure configured of multiply layers is realized. In the past, the number of required metal wiring layers was between 2 and 3 in case of a high integrated circuit device, such as a microprocessor; however, the number of the metal wiring layers are now being increased between 4 and 6. It is natural that the wiring layers will be further increased in proportion to higher integration hereafter.

For the structure of such wiring layers, tungsten of excellent step coverage and conductivity is mainly used. One of methods for depositing this tungsten is a chemical vapor deposition method, which is widely used. Furthermore, this chemical vapor deposition method is applied to an oxidation film serving as an isolation film between material films of conductivity, such as a SiO₂ film using various chemicals, and a high dielectric film, such as Si₂N₄, Ta₂N₅, BST, PZT, Al₂O₃, which is used as a dielectric material in a memory device, such as a dynamic random access memory or a flash memory, to form a film.

FIG. 1 is a cross sectional view of the conventional chemical vapor deposition apparatus for depositing a thin film to the surface of a wafer. Referring to FIG. 1, the conventional chemical vapor deposition apparatus comprises a process chamber 10, in which deposition of a thin film is carried out, an inlet gas line 11, a shower head 12 for injecting reaction gas, a heater 13 made of ceramic or AlN, on which a wafer is placed, a pumping line 14 for discharging reaction gas, a heater supporting member 15 for supporting the heater, and a bellows 16.

In the conventional chemical vapor deposition apparatus, one of the most important factors affecting uniformity in thickness of a thin film deposited on the surface of the wafer is uniformity in temperature of the surface of the heater, on which the wafer is placed. With the conventional chemical vapor deposition apparatus, however, the temperature is not uniform all over the heater 13 due to array of thermal devices or other external cause. Consequently, a relatively thick film is formed on the surface of the wafer at the area of the heater 13 having temperature higher than the other area of the heater 13, while a relatively thin film is formed on the surface of the wafer at the area of the heater 13 having temperature lower than the other area of the heater 13, which leads to lack of uniformity in thickness of the whole film deposited by the chemical vapor deposition apparatus.

### DISCLOSURE OF INVENTION

Therefore, the present invention has been made in view of the above problems, and it is an object of the present invention to provide a chemical vapor deposition apparatus for maintaining uniformly temperature of the heater on which a wafer is placed.

It is another object of the present invention to provide a chemical vapor deposition apparatus for forming a thin film of uniform thickness on the surface of a wafer.

In accordance with the present invention, the above and other objects can be accomplished by the provision of a chemical vapor deposition apparatus comprising: a process chamber; an inlet gas line; a shower head; a heater; a pumping line; a heater supporting member, and a bellows, the improvement of apparatus comprising a thermal insulation reflecting plate for maintaining uniformly temperature of the surface of the heater, on which a wafer is placed.

Preferably, the thermal insulation reflecting plate may be made of ceramic or metal with high reflection rate and high thermal insulation efficiency.

The thermal insulation reflecting plate may surround the bottom of the heater or the bottom and the sides of the heater. Alternatively, the thermal insulation reflecting plate may be provided below the heater or between the heater and the heater-supporting member.

Preferably, the thermal insulation reflecting plate may be attached to the heater or the heater-supporting member by means of fixing pins.

The thermal insulation reflecting plate may be provided with an open area applied to the temperature of an area which is different from that of the other area, or the thermal insulation reflecting plate may be applied to an area with temperature different from that of the other area for compensating for non-uniform temperature of the surface of the heater, on which the wafer is placed.

### BRIEF DESCRIPTION OF THE DRAWINGS

The above and other objects, features and other advantages of the present invention will be more clearly understood from the following detailed description taken in conjunction with the accompanying drawings, in which:

FIG. 1 is a cross sectional view of the conventional chemical vapor deposition apparatus;

FIG. 2 is a cross sectional view of a chemical vapor deposition apparatus according to the present invention;

FIG. 3A shows a heater with temperature not uniform thereon;

FIG. 3B shows a thermal insulation reflecting plate for compensating for temperature of the heater shown in FIG. 3A;

FIGS. 4 and 5 show different structures of a thermal insulation reflecting plate according to the present invention, respectively;

FIGS. 6 to 8 show various different arrangements of a thermal insulation reflecting plate according to the present invention, respectively.

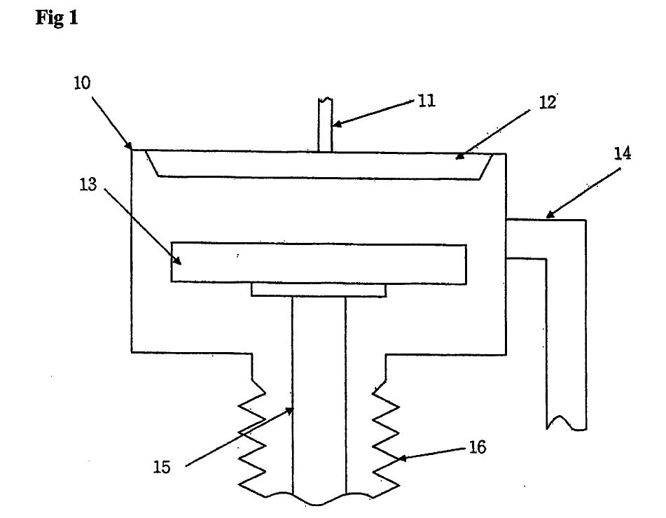

### BEST MODE FOR CARRYING OUT THE INVENTION

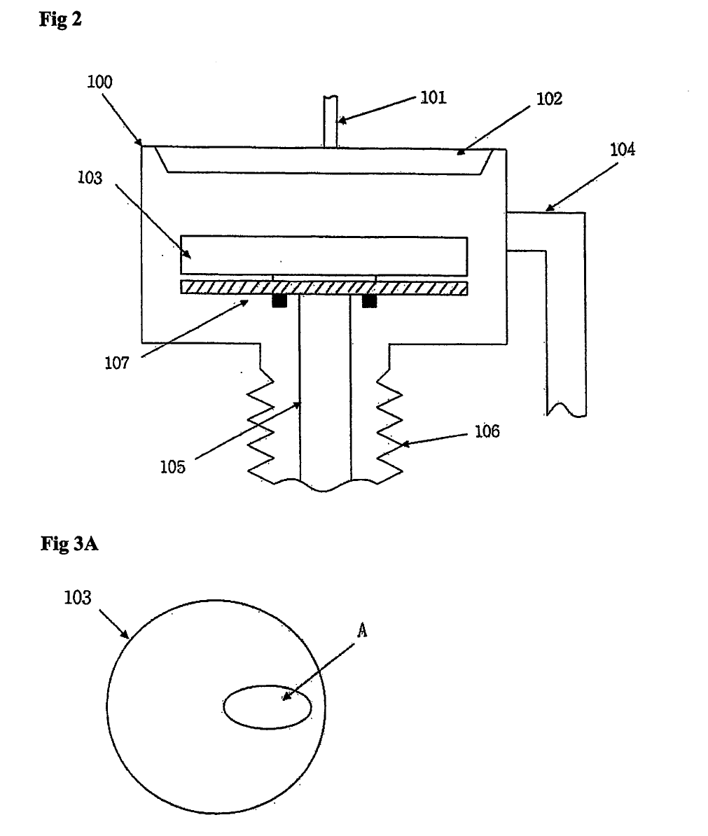

FIG. 2 is a cross sectional view of a chemical vapor deposition apparatus according to the present invention.

The chemical vapor deposition apparatus comprises a process chamber 100, an inlet gas line 101, a shower head 102, a heater 103, a pumping line 104, a heater supporting member 105, a bellows 106, and a thermal insulation reflecting plate 107.

The thermal insulation reflecting plate is an important component of the present invention, which distinguishes the chemical deposition apparatus according to the present invention from the conventional chemical deposition apparatus. The thermal insulation reflecting plate serves to maintain uniformly temperature all over the heater 103. The temperature of the surface of the heater, on which the wafer is placed, may be low or high locally due to array of thermal devices or other external cause. In this case, the temperature of the surface of the heater at the area where the temperature is low or high as compared to the other area is compensated to maintain uniformly the temperature all over the heater 103.

The structure of the thermal insulation reflecting plate and a method for controlling temperature of the heater using the thermal insulation reflecting plate will now be described.

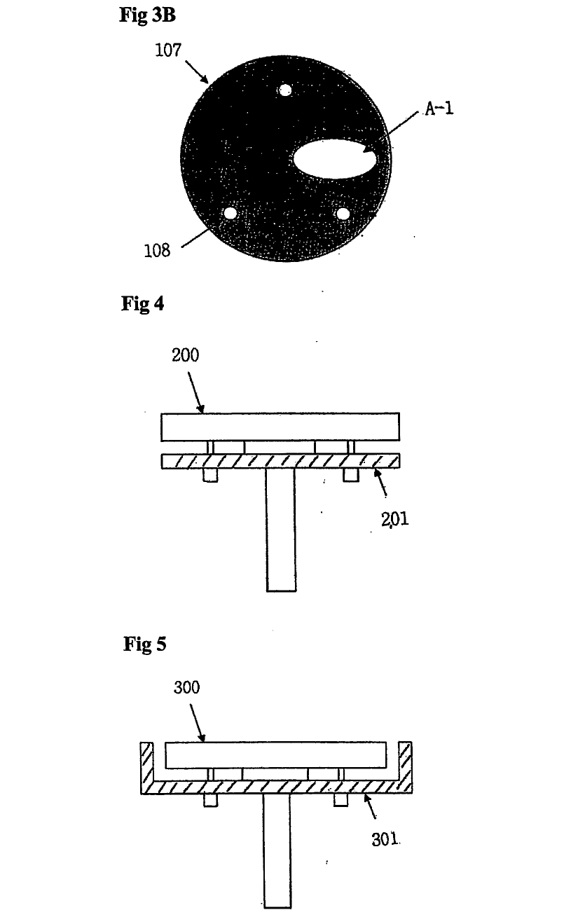

FIG. 3A shows a heater 103 with temperature not uniform thereon, and FIG. 3B shows a thermal insulation reflecting plate 107 for compensating for temperature of the heater 103 shown in FIG. 3A.

It is assumed that there is an area of relatively high or low temperature among the whole area of the heater 103, as indicated by reference symbol “A” of FIG. 3A. For example, in case that the temperature of the “A” area is higher than that of the other area, the thickness of the deposited film formed on the “A” area is thicker than that of the deposited film formed on the other area.

In order to lower the temperature of the “A” area, the thermal insulation reflecting plate 107 with an open area indicated by reference symbol “A-1” as shown in FIG. 3B is provided below the heater 103. Preferably, the thermal insulation reflecting plate 107 may be made of ceramic or metal with high reflection rate and high thermal insulation efficiency, such as inconel. Preferably, the thermal insulation reflecting plate 107 may surround the bottom of the heater 103 or the bottom and the sides of the heater 103. The thermal insulation reflecting plate 107 is connected to the heater 103 by means of several fixing pins 108.

Since the thermal insulation reflecting plate 107 for preventing heat loss of the heater is not provided at the “A-1” area, the temperature of “A” area, which is higher than that of the other area, becomes low, with the result that the temperature is uniform all over the heater 103.

On the contrary, in case that the temperature of the specific area of the heater 193 is lower than that of the other area, the thermal insulation reflecting plate 107 is applied to the area with the low temperature to raise the temperature so that the temperature is maintained uniformly all over the heater 103.

According to the present invention, the thermal insulation reflecting plate 107 for compensating for the temperature of the specific area, which is higher than that of the other area, is applied to the heater so that the temperature is maintained uniformly all over the heater 103. Furthermore, as the temperature is maintained uniformly all over the heater 103, the thickness of the thin film deposited on the surface of the wafer become more uniform enough to manufacture semiconductor device of high efficiency.

FIGS. 4 and 5 show different structures of a thermal insulation reflecting plate according to the present invention, respectively.

As shown in FIG. 4, a thermal insulation reflecting plate 201 may surround the bottom of a heater 200.

Alternatively, a thermal insulation reflecting plate 301 may surround the bottom and the sides of a heater 300, as shown in FIG. 5.

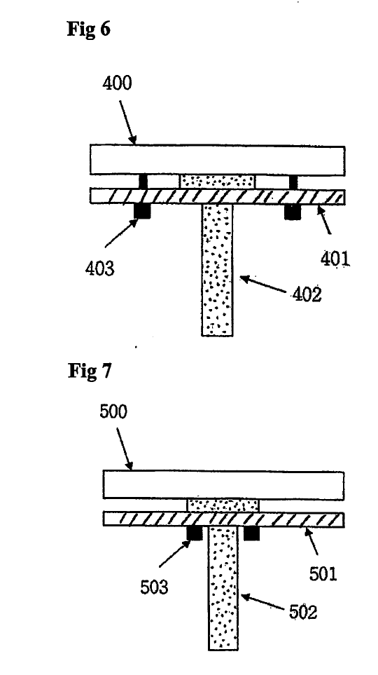

FIGS. 6 to 8 show various different arrangements of a thermal insulation reflecting plate according to the present invention, respectively.

As shown in FIG. 6, a heater 400 is disposed on a heater supporting member 402, and a thermal insulation reflecting plate 401 is attached to a heater 400 by means of fixing pins 403.

As shown in FIG. 7, a heater 500 is disposed on a heater supporting member 502, and a thermal insulation reflecting plate 501 is attached to the heater supporting member 502 by means of fixing pins 403.

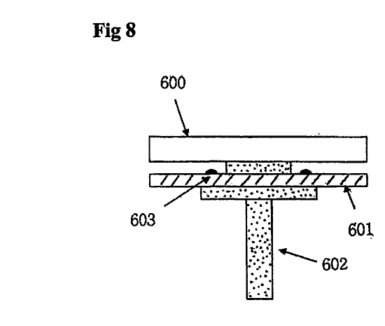

As shown in FIG. 8, a heater 600 is disposed on a heater supporting member 602. A thermal insulation reflecting plate 601 is provided on the heater supporting member 602, and the thermal insulation reflecting plate 601 is attached to the heater supporting member 602 by means of fixing pins 603.

### INDUSTRIAL APPLICABILITY

As apparent from the above description, the present invention uses a thermal insulation reflecting plate provided at the lower part of a heater or at the lower part and the sides of the heater to maintain temperature uniformly all over the heater so that a thin film of uniform thickness is deposited on the surface of a wafer.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

What is claimed is:

1. A chemical vapor deposition apparatus comprising: a process chamber; an inlet gas line; a shower head; a heater; a pumping line; a heater supporting member; and a bellows, the improvement of apparatus comprising a thermal insulation reflecting plate for maintaining uniformly temperature of the surface of the heater, on which a wafer is placed.

2. The apparatus as set forth in claim 1, wherein the thermal insulation reflecting plate is made of ceramic or metal with high reflection rate and high thermal insulation efficiency.

3. The apparatus as set forth in claim 1, wherein the thermal insulation reflecting plate surrounds the bottom of the heater or the bottom and the sides of the heater.

4. The apparatus as set forth in claim 1, wherein the thermal insulation reflecting plate is provided below the heater or between the heater and the heater supporting member.

5. The apparatus as set forth in claim 4, wherein the thermal insulation reflecting plate is attached to the heater or the heater supporting member by means of fixing pins.

6. The apparatus as set forth in claim 1, wherein the thermal insulation reflecting plate is provided with an open area applied to the temperature of an area which is different from that of the other area, or the thermal insulation reflecting plate is applied to an area with temperature different from that of the other area for compensating for non-uniform temperature of the surface of the heater, on which the wafer is placed.
